(19) United States
(12) Patent Application Publication
(10) Pub. No.: US 2022/0021330 A1
(43) Pub. Date: Jan. 20, 2022

(54) LIGHTWEIGHT SOLAR PANEL WITH SUPPORT SHEET

(71) Applicant: AmberWave, Inc., Salem, NH (US)

(72) Inventor: Anthony Lochtefeld, Ipswich, MA (US)

(21) Appl. No.: 17/379,033

(22) Filed: Jul. 19, 2021

Related U.S. Application Data
(60) Provisional application No. 63/053,285, filed on Jul. 17, 2020.
(60) Provisional application No. 63/136,319, filed on Jan. 12, 2021.

(51) Int. Cl. H02S 20/25; H02S 30/00; H01L 31/048

(52) U.S. Cl. CPC H02S 20/25; H01L 31/048; H02S 30/00

(57) ABSTRACT

A solar cell roofing system that includes a solar cell module including at least one solar cell that is laminated to a metal support sheet; and at least one bracket having a first type attachment point for engaging a standing seam of a standing seam metal roof and a second type attachment for engaging the metal support sheet of an adjacent solar cell module. During engagement of the solar cell module to the bracket, and engagement of the bracket to the standing seam, at least the metal support sheet is engaged in tension.

### CROSS REFERENCE TO RELATED APPLICATION

The present invention claims the benefit of U.S. provisional patent application 63/053,285 filed Jul. 17, 2020 the whole contents and disclosure of which is incorporated by reference as is fully set forth herein. The present invention also claims the benefit of U.S. provisional patent application 63/136,319 filed Jan. 12, 2021 the whole contents and disclosure of which is incorporated by reference as is fully set forth herein.

### TECHNICAL FIELD

The present disclosure relates to solar power, and more particularly relates to mechanisms for engaging solar panels to roofing systems.

### BACKGROUND INFORMATION

Low-rise, e.g., 1 story or 2 story buildings, having metal roofing, e.g., Commercial and Industrial (C&I) buildings, comprise a major fraction of C&I buildings in the US and other countries. For example, it is believed that metal roofing for C&I buildings amounts to at least 6 billion square feet installed in North America alone. They are often lightly constructed and cannot safely support the weight of mainstream solar panels based on silicon (Si) solar cells (weighing about 3 pounds per square foot, typically) without structural analysis and reinforcement of the building. This is often prohibitively expensive.

### SUMMARY

The present disclosure provides methods and structures for providing solar cell modules that can be mounted to a metal standing seam roof.

In one embodiment, a solar cell roofing systems is described that includes a solar cell module including at least one solar cell that is laminated to a metal support sheet; and at least one bracket having a first type attachment point for engaging a standing seam of a standing seam metal roof and a second type attachment for engaging the metal support sheet of an adjacent solar cell module. During engagement of the solar cell module to the bracket, and engagement of the bracket to the standing seam, at least the metal support sheet is engaged in tension.

In some embodiments, the solar cell module is planar. In some embodiments, of the solar cell roofing system, sidewalls along a length of the second type attachment point are perpendicular to sidewalls along a height of the first type attachment point. The first type attachment point can include a fastener for friction engagement to the standing seam. The second type attachment point can include a fastener for extending through an opening of the sidewalls of the second type attachment point, wherein the fastener extends through an opening through a portion of the metal support sheet that is positioned within the second type attachment point. The metal supporting sheet can have a thickness ranging from 24 gauge to 30 gauge.

In another embodiment, a solar cell roofing system is provided that includes a solar cell module including at least one solar cell that is laminated to a metal support sheet, wherein the edges of the metal support sheet are formed to provide that the solar cell modules are titled towards a light source in a position engaged to a standing seam metal roof. In this embodiment, the solar cell roofing system also includes at least one bracket having a first type attachment point for engaging a standing seam of a standing seam metal roof and a second type attachment for engaging the metal support sheet of the solar cell module.

In some embodiments, an angle of tilt to provide that the at least one solar cell is titled towards the light source may range from 5 degrees to 25 degrees. The angle of tilt defined at an intersection of the back surface of the metal supporting sheet that is underlying the solar cells and an upper surface of the standing seam metal roof. In some examples, the metal supporting sheet has a thickness ranging from 24 gauge to 28 gauge.

In yet another embodiment, a solar cell roofing system is described that includes at least one solar cell that is laminated to a metal support sheet, wherein the edges of the metal support sheet are formed to provide that the edges of the metal support sheet function as stanchions for direct contact mounting the edges of the metal support sheet to a roof surface so that an air passage is positioned between the roof surface and the metal support sheet. In some examples of this embodiment, the edges of the metal support sheet that function as stanchions have a base portion with an opening present therethrough. In some examples, a portion of the metal support sheet that is present between the edges that are formed to provide the stanchions is planar. The metal supporting sheet has a thickness ranging from 24 gauge to 28 gauge.

In an even further embodiment, a solar cell roofing system is described that includes a solar cell module including at least one solar cell that is laminated to a metal support sheet, the edges of the metal support sheet are formed to provide a bracket profile for fastening to a standing seam of a standing seam roof, wherein the bracket profile includes a first type attachment point for engaging a standing seam of a standing seam metal roof and a second type attachment for engaging the metal support sheet of an adjacent solar cell module. In some examples of this embodiment, an air passage is positioned between the standing seam roof and the metal support sheet. Further, the metal supporting sheet can have a thickness ranging from 24 gauge to 28 gauge.

In yet an even further embodiment, a solar cell roofing system is provided that includes at least one solar cell that is laminated to a metal roofing panel, in which the edges of the metal roofing panel are formed to provide standing seam profile including a male leg and a female leg at opposing ends of the metal roofing panel. In some embodiments, the at least one solar cell is engaged to a portion of the metal roofing panel that is positioned between the male leg and female leg. In some examples, the male and female ends of abutting panels having the standing seam profile are seam joined for a roofing installation. The metal roofing panel has a thickness ranging from 20 gauge to 26 gauge.

In another embodiment, a solar module is provided that includes at least one solar cell; and a metal support sheet that is laminated to the at least one solar cell, wherein at least one edge portion of the metal support sheet has a sigmoidal geometry from a perspective of a side view. In some examples, the at least one solar cell is present on a planar portion of the metal support sheet. In some examples, the at least one solar cell does not extend into the at least one edge portion of the metal support sheet. In some instances of the solar module, in which the engagement of the at least one solar cell to the metal support sheet is by being laminated, the solar cell is a component of a material stack that includes a back sheet encapsulant on the metal support sheet, a back sheet layer on the back sheet encapsulant, a back end encapsulant on the back sheet layer, the at least one solar cell present on the back end encapsulant, a front end encapsulant present on the at least one solar cell, and a polymer front sheet atop the front end encapsulant. In some examples, the polymer front sheet of the solar cell module includes a fluoropolymer composition. The polymer front sheet can be composed of ethylene tetrafluoroethylene (ETFE). In one example, the polymer front sheet has a thickness ranging from 25 microns to 200 microns.

In some examples, at least one of the back sheet encapsulant, the back end encapsulant and the front end encapsulant is comprised of a polymeric composition. The polymeric composition for at least one of the back sheet encapsulant, the back end encapsulating and the front end encapsulant can include a composition selected from the group consisting of ethylene-vinyl acetate (EVA), thermoplastic polyurethane, polyolefin and combinations thereof. In some examples, the at least one of the back sheet encapsulant, the back end encapsulant and the front end encapsulant has a thickness ranging from 100 microns to 500 microns.

In some examples of this embodiment, the solar cell includes a type IV semiconductor having an n-type doped region and a p-type doped region.

In some examples of this embodiment, the back sheet layer provides for electrical isolation between the metal support sheet and the at least one solar cell. In some embodiments, the back sheet layer is comprised of a polymeric material. In some examples, the back sheet layer is comprised of polyethylene terephthalate (PET).

In some examples of this embodiment, the metal support sheet has a composition selected from the group consisting of steel, galvanized steel, aluminum, galvalume and combinations thereof. The metal supporting sheet can have a thickness ranging from 24 gauge to 30 gauge.

In another embodiment, a method of forming a solar cell module is disclosed. The method may include laminating a solar cell to a portion of a metal support sheet. The solar cell can be laminated to the metal support sheet with a material stack including at least one encapsulant layer, wherein at last one edge portion of the metal support sheet is exposed. The method may further include deforming the at least one edge portion that is exposed onto a portion of the material layer including the encapsulant layer to enclose the at least one edge in a fold having a sigmoidal geometry from a perspective of a side view. In one embodiment, the fold having the sigmoidal geometry seals the at least one edge portion of the metal support sheet.

In some embodiments of the method, a base of the material stack including at least one encapsulant layer is present on an upper surface of the metal support sheet. Deforming the at least one edge portion can include a first fold operation to deform the metal support sheet to encapsulate the at least one edge in a first curve of the metal support sheet, wherein the first curve is providing the lower curve of the sigmoidal geometry. Deforming the at least edge portion can include a second folding operation to deform the metal support sheet in an opposite direction as the first forming operation that provided the first curve, wherein the second folding operation provides a second curve that provides an upper curve of the sigmoidal geometry.

### BRIEF DESCRIPTION OF THE DRAWINGS

These and other features and advantages of the present invention will be better understood by reading the following detailed description, taken together with the drawings wherein:

FIG. 1A is an exploded view of the layer structure for one embodiment of a solar cell module with a metal support sheet, in accordance with the present disclosure.

FIG. 1B is a side cross-sectional of an assembled solar cell module with metal support sheet as depicted in FIG. 1A.

FIG. 1C is a side cross-sectional view of another embodiment of an assembled solar cell module, in which the edges of the solar cell module that are present atop the metal supporting sheet extend to the edges of the metal supporting sheet.

FIG. 2A is a side cross-sectional view of a standing seam roof panel in accordance with one embodiment of the present disclosure.

FIG. 2B is a top down view of a standing seam roof panel, in accordance with one embodiment of the present disclosure. FIG. 2B includes a cross-section line corresponding to the cross-sectional view shown in FIG. 2A.

FIG. 3 is a side cross-sectional view of three panels of a standing seam roof, in which adjacent panels are joined using standing seams, in accordance with one embodiment of the present disclosure.

FIG. 4A shows a top down perspective view of a solar panel with metal support sheet.

FIG. 4B shows a cross-sectional view of the solar panel with metal support sheet shown in FIG. 4A.

FIG. 5A is a top-down perspective view of a bracket system that could be used for attaching solar cell modules to standing seam rooftops, in accordance with one embodiment of the present disclosure.

FIG. 5B depicts the same bracket system in cross-section along section line B-B of FIG. 5A.

FIG. 5C depicts a bottom-up perspective view of the bracket system depicted in FIG. 5A.

FIG. 6 depicts solar panel modules including metal support sheets mounted on a standing seam metal rooftop, in accordance with one embodiment of the present disclosure.

FIG. 7 depicts a top-down perspective view of a solar panel module with metal support sheet mounted on a standing seam metal rooftop, using the bracket system shown in FIGS. 5A and 5B, in accordance with one embodiment of the present disclosure.

FIG. 8A illustrates a side cross-sectional view of a metal supporting sheet having solar cells engaged thereto, in which the solar cells are offset from the center of the metal support sheet, in accordance with one embodiment of the present disclosure.

FIG. 8B illustrates a side cross-sectional view of the metal supporting sheet depicted in FIG. 8A following roll forming processing, in which the roll forming processes deforms the edges of the metal supporting sheet to tilt solar cells to face a light source when the metal support sheet is engaged to a standing seam metal roofing system, in accordance with one embodiment of the present disclosure.

FIG. 9 is a side cross-sectional view depicting a solar cell module including the metal support sheet depicted in FIG. 8B, in which the solar cell module is engaged to a standing seam metal roofing system, in accordance with one embodiment of the present disclosure.

FIG. 10A is a side cross-sectional view depicting a solar cell module including a metal support sheet prior to roll forming, in which the solar cells are positioned to allow for roll forming into a geometry for mounting of the solar cell module through fasteners to a metal roof structure in scenarios in which penetration of the roof with the fasteners is possible.

FIG. 10B is a side cross-sectional view depicting the solar cell module depicted in FIG. 10A following roll forming, in which the roll forming of the metal support sheet provides edges shaped to accommodate attachment of the solar cell module directly to the underlying roof without mounting brackets, in accordance with one embodiment of the present disclosure.

FIG. 11 is a side cross-sectional view of solar cell modules including brackets that are roll formed into the edges of the metal support sheet for the modules, in which the brackets provide the attachment points for the solar cell modules to a standing seam metal roof, in accordance with one embodiment of the present disclosure.

FIGS. 12A-12C illustrate side cross sectional views of a solar cell module that is laminated directly to a roofing panel, in accordance with another embodiment of the present disclosure.

FIG. 13 shows a side cross-sectional view of an assembled metal rooftop of the metal roof panels 200a depicted in FIGS. 12A-12C.

FIGS. 14A and 14B depict another embodiment of the present disclosure, in which an edge fold can be introduced to the solar cell structure via roll forming or other bending methods. FIGS. 14A and 14B are side perspective views.

FIGS. 15A, 15B and 15C depict another embodiment of the present disclosure, in which two edge folds are introduced to the solar cell structure. FIGS. 15A, 15B and 15C are side perspective views.

### DETAILED DESCRIPTION OF THE PREFERRED EMBODIMENTS

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. The term “top view” in the drawings of the supplied roof panels, brackets etc. indicates the orientation of the structure as the structure would be installed on a roofing surface. For purposes of the description hereinafter, the terms “upper”, “lower”, “right”, “left”, “vertical”, “horizontal”, “top”, “bottom”, and derivatives thereof shall relate to the embodiments of the disclosure, as it is oriented in the drawing figures. The terms “positioned on” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

The present disclosure provides a lightweight solar panel having a support sheet for engaging the panel to a metal roofing system. It has been determined that while there are lightweight silicon (Si) photovoltaic (PV) module alternatives that can weigh well under 3 lbs. per square foot, in those instances, the weight savings are generally achieved by reducing the module packaging. This can include using a clear polymer front sheet instead of glass, and eliminating the aluminum frame typical of mainstream silicon (Si) photovoltaic (PV) modules. It has been determined that these types of revisions result in modules that may not be mechanically robust, as the lightweight packaging does not provide sufficient structural support for the silicon (Si) solar cells. Silicon solar cells are brittle and crack easily under flexure. In addition, in cases where lightweight PV modules have been applied to metal rooftops, they have typically been attached using adhesives directly to the metal. Adhesive module attachment to existing buildings, applied in an outdoor environment, can lead to inconsistent results and reduced service life compared to traditional PV module mounting approaches.

The methods and structures described herein can provide for ultra-lightweight photovoltaic (PV) modules using silicon (Si) solar cells for application to metal building rooftops. In some embodiments, a metal support sheet is integrated with a solar module, to provide sufficient rigidity to limit module flexure during module shipping, installation, and operation, thereby preventing the silicon (Si) solar cells from cracking. The metal support sheet is lightweight. For example, the metal support sheet may have a weight ranging from 0.6 lbs. per square foot (PSF) to 1.0 PSF. In one example, the metal support sheet may have a weight on the order of approximately 0.75 PSF. As discussed herein, the metal support sheet can enable easy clip-on attachment to a very common metal roof design, so-called standing-seam metal roofs.

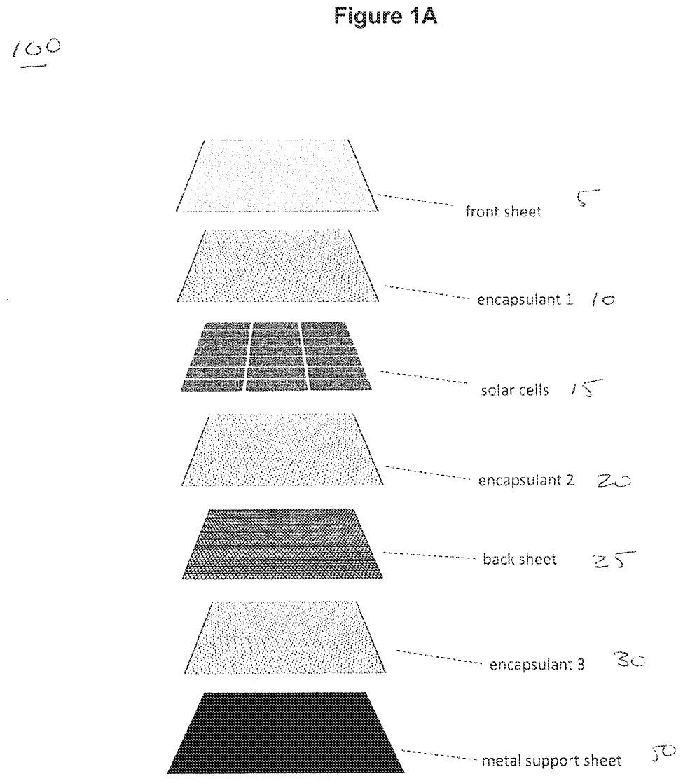

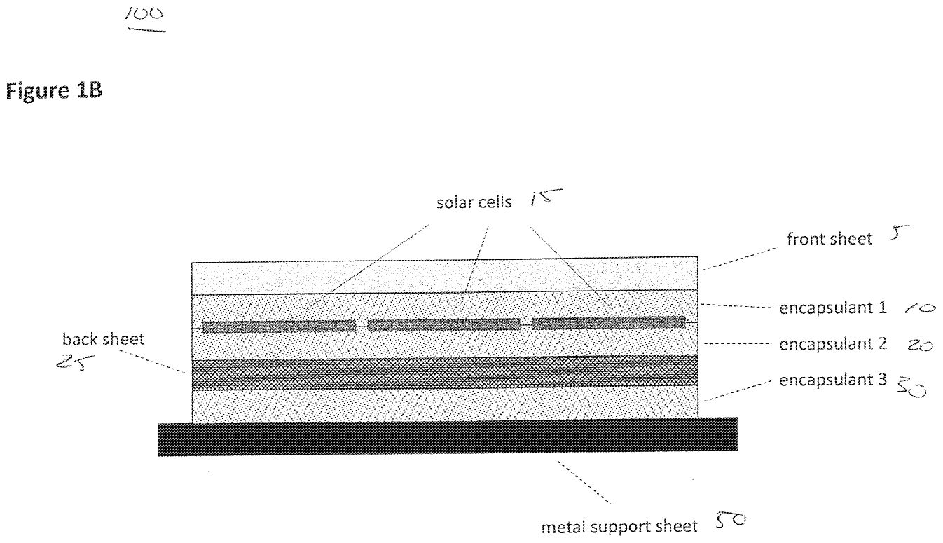

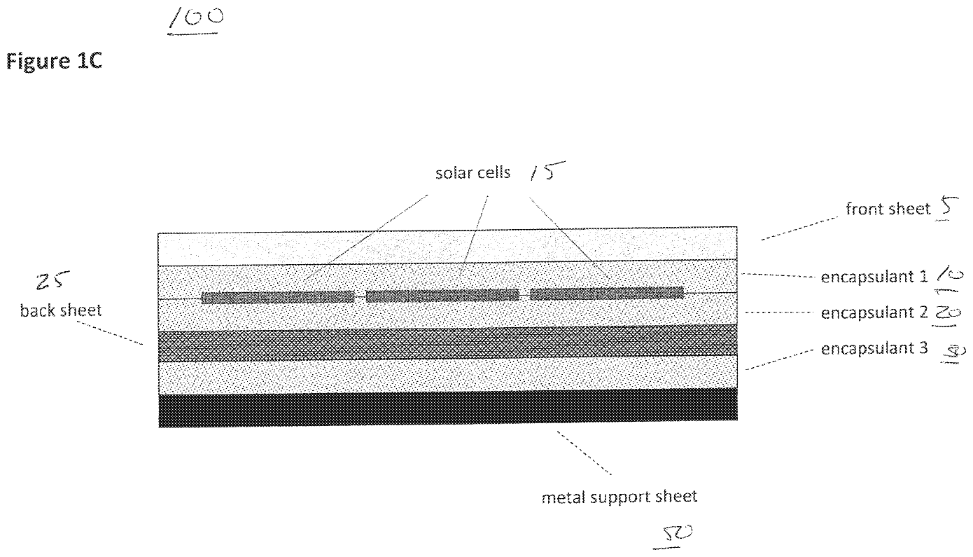

FIG. 1A shows an exploded view of the layer structure for one embodiment of a solar module 100 which includes a metal support sheet 50, in accordance with the present disclosure. FIG. 1B illustrates the elements of the solar module 100 depicted in FIG. 1A in an assembled state, and FIG. 1B illustrates a side cross-sectional view of the solar module 100. The solar module 100 will be described as having a front (or upper surface) that is the light receiving end of the device. The back surface of the solar module 100 will be described as the surface (i.e, end) of the device that is opposite the light receiving end of the device.

Referring to FIGS. 1A and 1B, instead of the typical glass front sheet, the solar modules 100 of the present disclosure employ a polymer front sheet 5. In one example, the polymer front sheet 5 may be composed of a fluoropolymer type composition. For example, the polymer front sheet 5 can be composed of ethylene tetrafluoroethylene (ETFE). It is noted that ethylene tetrafluoroethylene (ETFE) is only one example of a fluoropolymer composition that is suitable for use as a polymer front sheet as a low weight alternative to a glass front sheet. In other examples, the polymer front sheet 5 may be composed of fluorinated ethylene propylene (FEP), or polyvinylidene fluoride (PVDF) or any combination of these compositions including combinations with ethylene tetrafluoroethylene (ETFE). The thickness of the polymer front sheet 5 may range from 25 microns to 200 microns or higher. In some examples, the thickness of the polymer front sheet 5 can range from 50 microns to 100 microns.

Referring to FIGS. 1A and 1B, in some embodiments, the solar module 100 may include at least three encapsulant layers 10, 20, 30. A first encapsulant layer 10 may be present between a back surface of the front sheet 5 and an upper surface of the solar cells 15. The upper surface (which may also be referred to as the front surface) of the solar cells 15 is the surface of the solar cells 15 that is positioned to be the face of the solar cells 15 for receiving the majority of light being received by the solar cells 15. The second encapsulant layer 20 is present between the back surface of the solar cells 15 and a front surface of a back sheet 25. Referring to FIG. 1B, in some embodiments, when the solar module 100 is assembled, a portion of the first and second encapsulate layers 10, 20 may contact one another in the space between adjacently positioned solar cells 15. The third encapsulant 30 is present between the back sheet 25 and the metal support sheet 50.

Each of the first, second and third encapsulant layers 10, 20, 30 may be composed of a polymeric composition. For example, at least one of the first, second and third encapsulant layers 10, 20, 30 may be composed of at least one of ethylene-vinyl acetate (EVA), thermoplastic polyurethane (TPU), polyolefin or a combination thereof. Each of the first, second and third encapsulant layers 10, 20, 30 may have an individual thickness ranging from 100 microns to 500 microns. In one example, each of the first, second and third encapsulant layers 10, 20, 30 may have an individual thickness ranging from 200 microns to 400 microns.

The solar cells 15 may be silicon (Si) type solar cells. For example, generally a solar cell is made of two types of semiconductors, called p-type and n-type silicon (Si). The p-type silicon is produced by adding atom, such as boron (B) or gallium (Ga), that have one less electron in their outer energy level than does silicon (Si). Because boron has one less electron than is required to form the bonds with the surrounding silicon atoms, an electron vacancy or “hole” is created. The n-type silicon (Si) is made by including atoms that have one more electron in their outer level than does silicon (Si), such as phosphorus (P). Phosphorus (P) has five electrons in its outer energy level, not four. It bonds with its silicon neighbor atoms, but one electron is not involved in bonding. Instead, the electron is free to move inside the silicon structure. A solar cell consists of a layer of p-type silicon (Si) placed next to a layer of n-type silicon (Si). This is only one example of a silicon (Si) solar cell and is provided for illustrative purposes only. It is not intended that the teachings of this description of the solar cells 15 be limiting.

For example, the solar cells 15 can be Passivated Emitter and Rear Contact (PERC) design, or Interdigitated Back Contact (IBC) design, or SHJ (Silicon Heterojunction) design. Alternately the solar cells 15 can be MWT (Metal Wrap Through) design. The interconnections between the cells can via soldering, or via conductive paste, or via a multi-wire technology used in conjunction with busbar-free cells, such as the SmartWire Connection Technology developed by Meyer Burger. Some of these approaches (IBC and MWT cells, and multi-wire with busbar-free cells) may reduce the occurrence or effect of cracking within solar cells, which is of particular importance for a lightweight and flexible or semi-flexible PV module. In some embodiments, the lateral dimensions of these solar cells can be about 125 mm or 156 mm square or semi-square, or larger, and the thickness can be about 80 to 200 microns.

The back sheet 25 can provide electrical isolation between the solar cells (and cell interconnects) and the metal support sheet 50. Referring to FIGS. 1A and 1B, the back sheet 25 can be a polymer material, such as Polyethylene terephthalate (PET), of for example 100-500 microns thickness. In some examples, the back sheet consists of multiple layers of barrier films and adhesives. Examples of film compositions that can be used in the back sheet 25 may include polyethylene terephthalate (PET), polyphenyl ether (PPE), polyethylene naphthalate (PEN) and combinations thereof.

The metal support sheet 50 can be a metal such as steel, galvanized steel, galvalume, or aluminum. Galvalume is a coating consisting of zinc (Zn), aluminum (Al) and silicon (Si) that is used to protect a metal (primarily steel) from oxidation. Galvalume is similar to galvanizing in that it is a sacrificial metal coating which protects the base metal. In some examples, galvalume is used to protect iron-based alloys that are prone to rust.

The metal support sheet 50 can be of gauge of approximately 24 to 28. In some examples, the metal support sheet 50 can have a gauge equal to approximately 24, 25, 26, 27, 28, 29 and 30. The aforementioned examples for the gauge thickness for the metal support sheet 50 may be used to provide a range of gauge thicknesses to describe the metal support sheet 50, in which one of the aforementioned examples provides a lower end of the range, and one of the aforementioned examples provide an upper end of the range.

Other elements of the solar module such as cell interconnects, bypass diodes, module connections and the junction box are not shown in FIGS. 1A and 1B, for the sake of clarity. However, these can be implemented as in mainstream Si PV modules, as would be understood by one skilled in the art. The edges of the metal support sheet can extend laterally beyond the edges of some or all of the other layers in the module stack, to allow for room for attachment hardware (such as clamps or screws) for attaching the module to the metal rooftop. The layer stack shown in FIG. 1A can be laminated in a photovoltaic (PV) solar module laminator using process conditions (heat, pressure, time, etc.) known in the art for making Si PV modules.

In some embodiments, module laminators follow a three step process for proper melting and curing of the encapsulant 10, 20, 30, and achieving a good quality lamination. In some embodiments, the laminator process can include a) heating of the module lay-up to required temperatures to perform the encapsulant (e.g., EVA) cross-linking step. b) Create vacuum to remove the air and avoid bubble formation. The time of applying a vacuum as well as the rate of evacuation can be varied to optimize the process and hence the end-result. Reducing the pressure too early or at a high rate will result in significant outgassing of the additives in the encapsulant like adhesion promoters and/or stabilizers, and hence result in a decreased quality of the solar cell modules 100, whereas applying the vacuum too late will lead to air inclusion and hence unwanted bubble formation. c) Application of pressure to ensure a good surface contact and adhesion between the different layers of the solar cell module 100.

During the process of lamination, the layered stack of material layers for the solar cell module 100 depicted in FIG. 1A is placed in the lamination machine and heated to a maximum of e.g. 135° C. for a period of e.g. approximately 20 minutes. The final product, i.e., stack of material layers for solar cell module 100 (as depicted in FIGS. 1B and 1C), that comes out is completely sealed. Excessive material for the encapsulant 10, 20, 30, e.g., EVA and TPU during the lamination are discarded.

FIG. 1B depicts an assembled solar module 100 with metal support sheet 50, consistent with the elements depicted in the exploded view that is illustrated in FIG. 1A. It is noted in FIG. 1B, the vertical scale has been exaggerated to allow the individual layers to be illustrated. It is noted that the upper surface of the solar module 100, as well as the metal support sheet 50, is planar. The term “planar” as used herein means a surface at which the curvature is zero. As illustrated in FIGS. 1A and 1B, the planar solar module has no curvature when viewed from a cross section, as depicted in FIG. 1B.

As shown in FIG. 1B, the layers of the solar module 100 on top of the metal support sheet 50 may not extend all the way to the edges of the metal support sheet 50, leaving some region of metal exposed. In the embodiment that is depicted in FIG. 1B, the edges of the metal support sheet 50 may then be processed using roll forming techniques, or some other technique of forming permanent bends in a metal sheet, as discussed below. The roll forming processes are performed after lamination of the solar cells 15 to the metal support sheet 50.

In some embodiments, as shown in FIG. 1C, the layers of the solar module 100 on top of the metal support sheet 50 can extend all the way to the edges of the metal support sheet 50. As noted, the back sheet 25 provides electrical isolation between the solar cells 15 (and cell interconnects) and the metal support sheet 50. As an alternative, it may be possible to eliminate the need for the back sheet 25 as well as for encapsulant sheet 30 present between the back sheet 25 and the metal support sheet 50, by using a thicker encapsulant sheet for the portion of the encapsulant (identified by reference number 20) that is in contact with the back surface of the solar cells 15. In this example, the portion of the encapsulant (identified by reference number 20) that is in contact with the back surface of the solar cells 15 may have a thickness ranging from e.g. 1000 to 2000 microns thick.

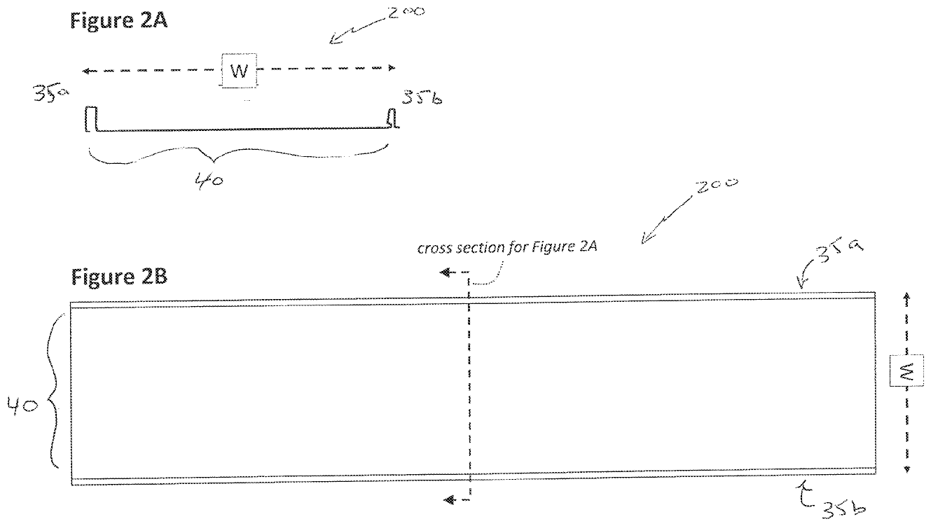

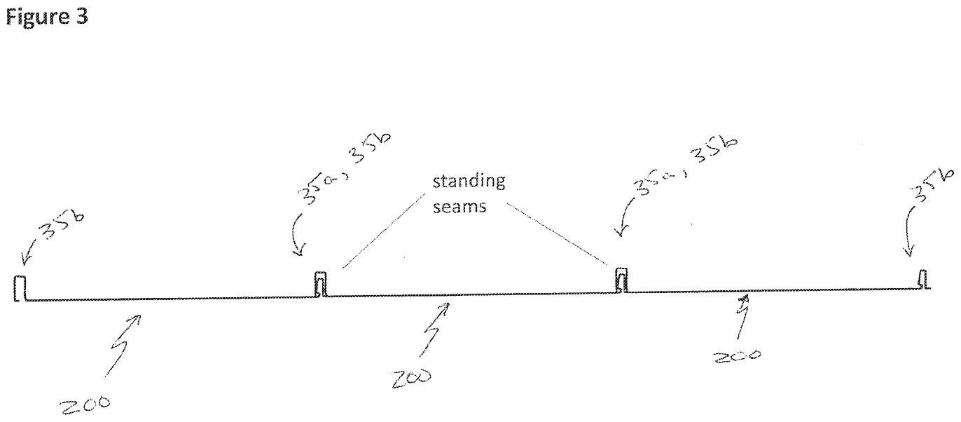

The solar module 100 depicted in FIGS. 1A-1C may be engaged to a metal roof system, such as a standing seam metal roof system, as depicted in FIG. 2A-3. FIG. 2A is a cross-sectional view of a standing seam roof panel 200. FIG. 2B is a top down view of the standing seam roof panel 200 that is depicted in FIG. 2A. FIG. 3 is a side cross-sectional view of three panels 200 of a standing seam roof, in which adjacent panels are joined using standing seams 35a, 35b.

FIG. 2A shows an illustration of a cross section of a representative standing seam metal roof panel 200, as part of a standing seam metal roof system. “Standing seam metal roofing” is defined as a concealed fastener metal panel system that features vertical legs and a broad, flat area between the two legs. The two legs may be referred to as including a male leg and a female leg that are configured to engage on another when identical roof panels 200 are seamed together. Referring to FIGS. 2A-3, the vertical legs, which may also be referred to as the standing seams, are identified by reference numbers 35a, 35b. The broad, flat area between the two legs is identified by reference number 40.

The standing seams 35a, 35b are also described as being raised seams, or vertical legs, that rise above the level of the panel's flat area. The main idea for standing seam systems is that the fastener is hidden, whether the panel is attached to the roof deck using a clip or is directly fastened to the decking material under the vertical leg using a fastener flange. A standing seam metal roofing system may include a number of panel profiles. The panel profile refers to the shape and way two or more panels are seamed together. In one embodiment, the panel profile may be a snap-lock type profile. Snap-lock profiles consist of panels that have been roll formed with specifically shaped edges, a male and female leg, that snap together and do not require hand or mechanical seaming during installation. Snap-lock profiles are attached to the roof deck using a clip that attaches to the seam and fastens underneath the panel.

Another profile for the metal roofing system is fastener flange panels. Fastener flange panels use a similar locking mechanism to snap-lock profiles; however, a true snap-locks allow for the system to float freely with its clip system, while fastener flange panels do not include this feature.

Another profile for metal roofing systems including standing seams may be referred to as a mechanical lock profile. A mechanical lock profile may include mechanically seamed panels that are roll formed with specific edges that line up with each other. With a mechanical lock profile, once the two panels are engaged, a hand or mechanical seamer is used to bend the edges and lock the panels together. There can be two different versions of mechanical seams: single lock 90-degree seams and double lock 180-degree seams.

In yet another example, the panel profile may be a batten panel profile. A batten panel roofing system is when two legs of the panels are roll formed and then butted up next to one another. From there, a metal cap goes over the legs to create a seam, and either snaps on or mechanically seams into place. The part that goes over the legs varies quite a bit, but there are two common types: tee seams and snap caps.

It is noted that the above profiles are provided for illustrative purposes only, and it is not intended that the methods and structures of the present disclosure be limited to only this example. Some examples of standing seam roof systems are the MR-24® by Butler, the SSRTM by Varco Pruden, LokSeam® by MCBI, CFR™ by Nucor, and various others.

Referring to FIGS. 2A-3, the standing seam metal roof panel 200 can have a width W ranging from 12″ to 36″. In another example, the standing seam roof panel 200 can have a width W ranging from 18″ to 24″. The length for the standing seam roof panel 200 can be up to 50 feet or more. FIG. 2B illustrates a top view of such a standing seam metal roof panel.

Standing seam metal roofs are designed to interlock at the edges, creating a “standing seam” that can be waterproof and avoids the need for any screws or roof penetrating connections. FIG. 3 shows three representative metal roof panels 200 interlocked by standing seams 35a, 35b.

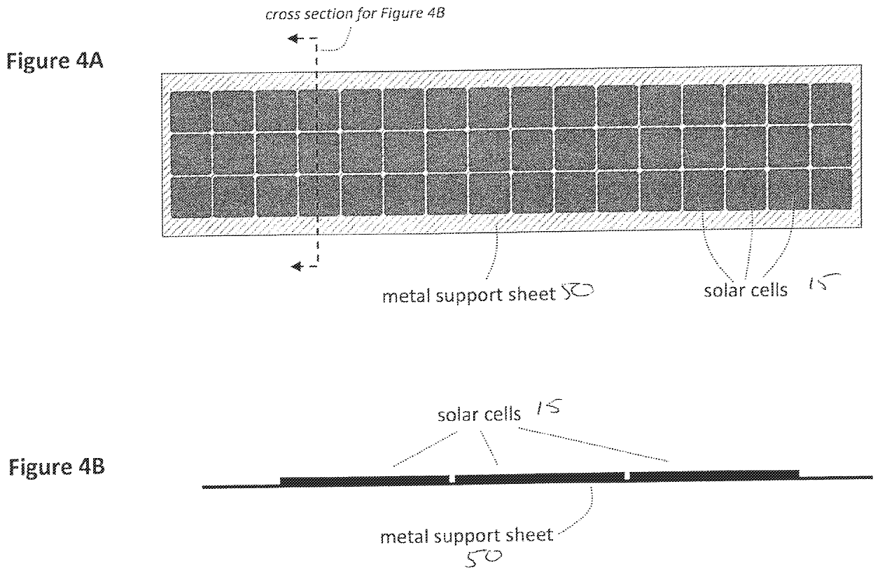

FIG. 4A shows a top-down view of a solar panel 100 with metal support sheet 50. In this figure, as well as in subsequent FIGS. 4B, 6, 7, 8A-B, 9, 10A-B, 11, 12B, 12C and 13, the solar cells and the metal support sheet are shown, while the other components (front sheet, back sheet, encapsulant layers, solar cell interconnects, bypass diodes, module connections, junction boxes, etc.) are omitted for the sake of clarity. FIG. 4B shows a cross section view of the solar panel with metal support sheet shown in FIG. 4A.

The solar panels 100, as depicted in FIGS. 1A-1C and 4A-4B, may be engaged to a metal roofing system by engagement to the raised seams 35a, 35b. In some embodiments, engagement of the solar panels 100 to the raised seams 35a, 35b includes a bracket system 300 that engages both the metal supporting sheet 50 of the solar cell modules 200 and the raised seams 35a, 35b of the metal roof panels 200.

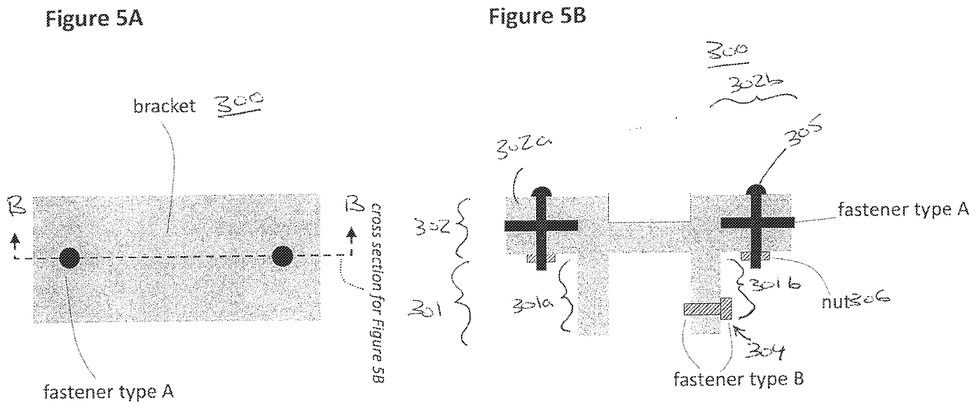

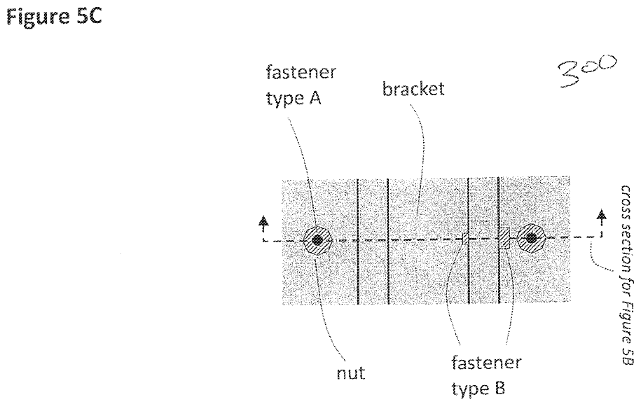

FIG. 5A shows a top-down view of a bracket system that could be used for attaching solar cell modules 100 to sealing seams 35a, 35b of a standing seam rooftop. FIG. 5B shows bracket 300 from FIG. SA in cross-section. The body of the bracket 300 may be composed of a metal or a polymer. For example, the bracket 300 may be composed of aluminum, and the bracket may be an extrusion or a casting. The body of the bracket 300 may include two attachment points. A first type attachment point 301 for engagement of the bracket 300 to a standing seam 35a, 35b. The first type attachment point 301 may be referred to as a standing seam engagement point. The engagement point may also be referred to as a standing seam clamp point of the bracket 300.

The first type attachment point 301 may include two vertically orientated sidewalls 301a, 301b. The sidewalls may be referred to as being vertically orientated, because their height is positioned at a substantially right angle to the horizontal surface of the roofing system that the bracket 300 is eventually mounted to. The spacing between the two sidewalls 301a, 301b of the first type attachment point 301 is selected so that the standing steam 35a, 35b can be positioned between the two sidewalls 301a, 301b when the bracket 300 is engaged to the roofing system of the adjacent roof panels 200 that are engaged by the sanding seams 35a, 35b.

Referring to FIG. 5B, at least one of the sidewalls 301a, 301b may include a roof seam engaging fastener 304. Although the roof seam engaging fastener 304 is depicted in only one sidewall of the first type attachment point 301 that is identified by reference number 301b, the roof seam engaging fastener 304 may be present through an opening through each of the sidewalls, e.g., both the first and second sidewalls identified by reference numbers 301a and 301b. The roof seam engaging fastener 304 may extend through an opening through the sidewall 301b. The roof seam engaging fastener 304 and the sidewall 301b may be in threaded engagement. In this manner, the roof seam engaging fastener 304 may be a screw, and the opening may be tapped to have a reciprocal thread. The positioning of the roof seam engaging fastener 304 may provide that the roof seam engaging fastener 304 engages the standing seam 35a, 35b of the standing seam metal panel roofing system. More specifically, the roof seam engaging fastener 304 may be rotated so that the end of the screw extends into contact in frictional engagement with the sidewalls of the standing seam 35a, 35b that is positioned between the sidewalls 301a, 301b of the first attachment point 301. The roof seam engaging fastener 304 may be designed so that it does not penetrate the standing seam 35a, 35b of the metal roof panel 200, but rather secures the bracket 300 to the standing seam 35a, 35b through friction.

The body of the bracket 300 may also include a second type of attachment point 302 that is employed to engage the body of the bracket 300 to the metal support sheet 50 of the solar module 100. In the embodiment depicted in FIGS. 5A and 5B, the body of the bracket may include two of the second type attachment points 302 on opposing sides of the bracket 300. In some embodiments, the first type attachment point 301 is centrally positioned on the body of the bracket 300 between the two second type attachment points 302 that are present on opposing sides of the bracket 300.

The second type attachment points 302 are configured so that when the bracket 300 is engaged to the standing seam 35a, 35b of the metal roofing system, and the metal support sheet 50 of the solar cell module 100 is engaged to the second type attachment point 302, the metal support sheet 50 is maintained in tension. This provides rigidity to the solar cell module 100 that is greater than the rigidity of the solar cell module 100 prior to being installed to the roofing system. The rigidity of the solar cell module 100 when the metal support sheet 50 is under tension due to engagement of the brackets 300 that are engaged to the metal support sheet 50, and the brackets 300 are engaged to the standing seam 35a, 35b is greater than the rigidity of the solar cell modules 100 when they are attached to a roofing system and under a compressive stress. For example, when the metal support sheet 50, i.e., the metal support sheet 50 and the remainder of the layers that provide the solar cell modules 100 are engaged to the standing seams 35a, 35b so that the metal support sheet 50 is suspended over the horizontal surface of the roofing system, the plane that the metal support sheet 50 is present on is substantially parallel to the plane defined by the horizontal surface of the roof panels 200. The horizontal surface that is parallel to the plane that the metal support sheet 50 is present on is the broad, flat area of the roof panels 200 identified by reference number 40. In some embodiments, when the bracket 300 is engaged to the standing seams 35a, 35b at the first type attachment point 301, and the metal support sheet 50 of the solar cell modules 200 are engaged to the second type attachment point 302 of the bracket 300, substantially the entirety of the metal support sheet 50 (and the associated solar cell modules 200) is planar. This mounting approach allows a thin metal support sheet to be used while maintaining planarity of solar cell modules 100, parallel to the underlying roof surface.

Referring to FIGS. 5A and 5B, each of the second type attachments 302 includes an upper sidewall 302a and a lower sidewall 302b that are positioned to allow for the metal support sheet 50 to be positioned therebetween. The spacing between the two sidewalls 302a, 302b of the second type attachment point 302 is selected so that the metal support sheet 50 can be positioned between the two sidewalls 302a, 302b.

The sidewalls 302a, 302b of the second type attachments 302 have a length that is along a plane substantially parallel to the plane defined by the horizontal surface of the roof panels 200 when the bracket 300 and the attached solar cell modules 100 are engaged to the metal roof system. The horizontal surface of the roof panels 200 that the solar cell modules 100 are present on is the broad, flat area of the roof panels identified by reference number 40. The length of the sidewalls 302a, 302b of the second type attachment point 302 are positioned to be perpendicular to the height of the sidewalls 301a, 301b of the first type attachment point 301. The outer sidewall surface of the sidewalls 301a, 301b for the first type attachment point 301 intersects the lower surface of the sidewall 302b for each of the second type attachment points 302 at a right angle a.

Referring to FIG. 5B, at least one of the sidewalls 302a, 302b of the second type attachment point 302 may include an opening for engaging a solar cell module engaging fastener 305. The fastener 305 may be present through an opening through each of the sidewalls, e.g., both the first and second sidewalls identified by reference numbers 302a and 302b. The solar cell module engaging fastener 305 may also extend through an opening of the metal supporting sheet 50 that is positioned in the second type attachment point 302 when the metal supporting sheet 50 is engaged to the bracket 300. The solar cell module engaging fastener 305 may engage a backing structure 306, in which the head of the solar cell module engaging fastener 305 is positioned to engage the upper sidewall 302a of the second type attachment point 302 and the backing structure 306 receives the opposing end of the solar cell module engaging fastener 305, wherein the backing structure 306 abuts the back surface of the lower sidewalls 302b. The fastener 305 may be a threaded fastener for engagement of a backing structure 306 having a receiving thread. The backing structure 306 may be engaged to the back surface of the sidewall 302b of the second type attachment point 302. The backing structure 306 may be a tapped boss in a casting that provides the body of the bracket 300. In other embodiments, the backing structure 306 may be engaged to the bracket 300 by welded or adhesive engagement. The solar cell module engaging fastener 305 may be a bolt, and the backing structure 306 may be nut. In some embodiments, as the solar cell module engaging fastener 305 extends through the openings of the sidewalls 302a, 302b and is present through the opening of the metal support sheet 50, wherein as the solar cell module engaging fastener 305 and backing structure 306 are tightened together a clamping force is applied to the metal support sheet 50 engaging the metal support sheet 50 within the second type attachment point 302. Although nut and bolt arrangements are depicted in FIG. 5B for the solar cell module engaging fastener 305 and backing structure 306 different types of mechanical fasteners may also be employed.

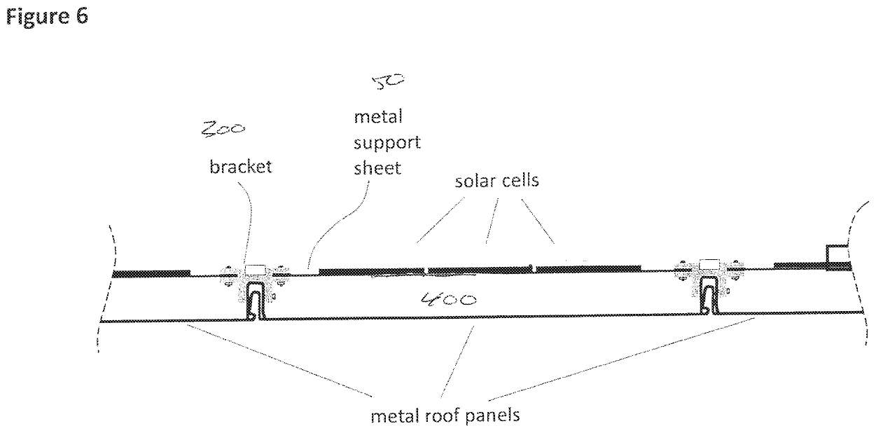

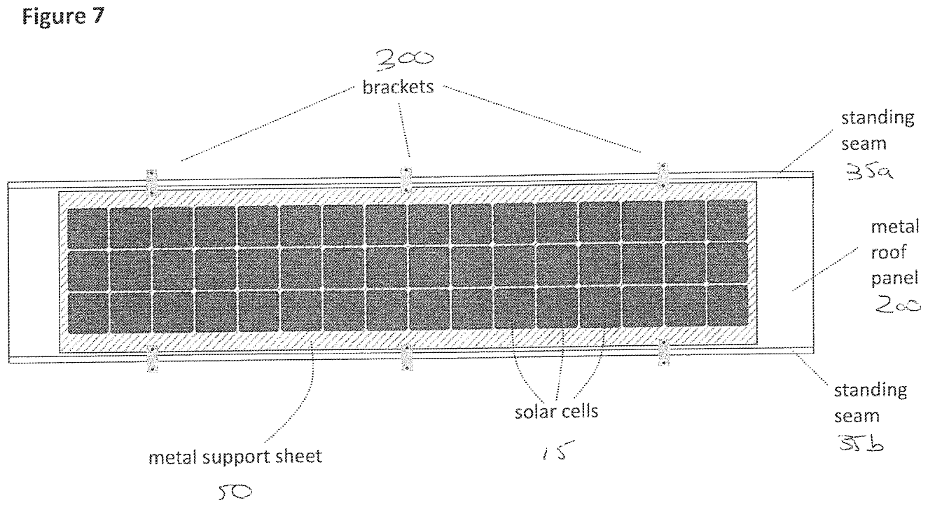

FIG. 6 shows solar panel modules 100 including metal support sheets 50 mounted on a standing seam metal rooftop (standing seam joined metal roof panels 200), using the bracket system (bracket 300) shown in FIG. 5. FIG. 7 shows a top-view of a solar cell modules 100 (solar panels) with metal support sheet 50 mounted on a standing seam metal rooftop, using the bracket system shown in FIGS. 5A-5C. In some embodiments, the solar cell module engaging fastener 305 can penetrate a hole drilled or punched through the solar panel metal support sheet 50, and could be secured by the nut. Mounting the solar cell modules 100 (solar panels) in this way, with spacing between the panels 100 and the metal roof panel 200, allows for circulation of air beneath the solar cell modules 100 and metal support sheet 50. In some instances, this arrangement provides an air passage 400 underlying the solar cell modules 100. This may have a cooling effect which will enable lower solar panel operating temperature, compared to solar panels adhered directly to metal roof panels, for example with adhesive. The bracket system shown in FIGS. 5A-7 is intended to be illustrative. Other types of brackets and fasteners to attach the solar panel with metal support sheet to the standing seams may be envisioned.

In addition, with this mounting approach, the brackets can maintain the solar panel metal support sheet in tension, which can prevent the solar panel and metal support sheet from flexing substantially under high winds or snow loads, even if the metal support sheet is very thin and lightweight. For example, by engaging the solar cell module 100 in tension, the metal support sheet 50 may employ a thin lightweight gauge on the order of 26 or greater, e.g., a gauge of 28, while maintaining sufficient rigidity for suitable operation.

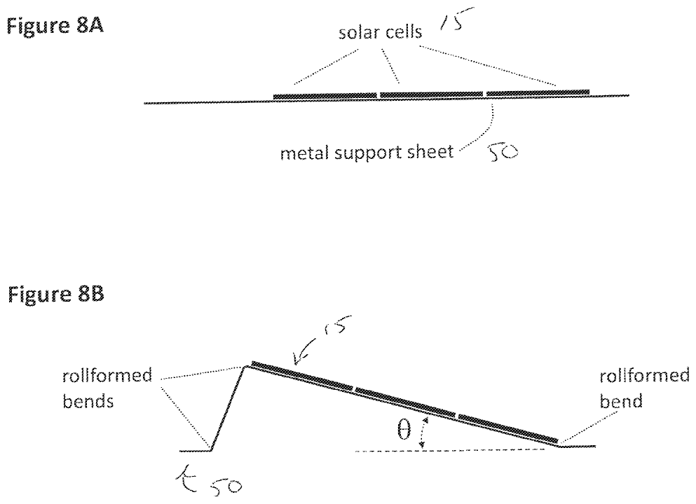

FIGS. 8A and 8B show, in cross-section, an alternative approach for forming a solar cell module 100 (solar panels) with metal support sheet 50. As shown in FIG. 8A, for this approach the metal support sheet 50 differs from that of FIG. 1 in that the metal support sheet 50 is substantially wider, and the solar cells 15 are offset to one side of center. The solar cell module 100 with metal support sheet 50, after lamination, can be passed through a metal roll forming tool to form the profile shown in FIG. 8B, where the solar cells 15 are tilted at an angle θ. The angle θ could be, for example, in the range of 5 degrees to 25 degrees. The tilt angle θ is selected to position the solar cells 15 to receive a greater degree of light from the sun compared to mounting the solar cells flat (i.e. with tilt angle θ of zero), while the solar cell modules 100 including the solar cells 15 are mounted to a standing seam metal roofing system.

Metal roll forming tools can be used in forming the metal support sheet 50 in for use with the metal roof systems described herein. Roll forming is a continuous bending operation in which a long strip of metal (typically coiled steel) is passed through consecutive sets of rolls, or stands, each performing only an incremental part of the bend until the desired cross-section profile is obtained. Roll forming is ideal for producing parts with long lengths or in large quantities. Such tools are made by, for example, the Bradbury Co., Inc. (Moundridge, Kans.) and would be suitable for the formation of bends in the solar panel with metal support sheet, as long as the solar the bends created do not intersect the silicon solar cells. Other methods and tools to introduce the bends illustrated in FIGS. 8 may be envisioned.

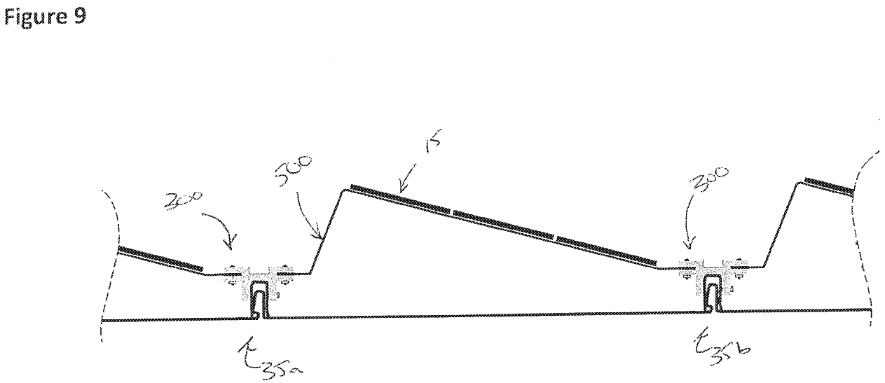

FIG. 9 shows solar panels, e.g., solar cell modules 100, with metal support sheets 50 having the profiles illustrated in FIG. 8B, mounted on a standing seam metal rooftop, using the bracket system (brackets 300) shown in FIGS. 5A-5C. For specifically, similar to the embodiments described with reference to FIGS. 6 and 7, in the embodiment that is depicted in FIGS. 9 the bracket 300 provides a first type attachment point 301 for engaging the standing seam 35a, 35b of the roofing system, and a second type attachment point 302 for engaging the metal support sheet 50 of the solar cell module 100.

This approach allows for rooftop mounting such that the solar panel is angled toward the sun to improve overall energy output, or to improve energy output at peak demand time of day, e.g., late afternoon and early evening. For example, in the northern hemisphere, a solar cell module 100 with a metal support sheet 50 having the profile depicted in FIGS. 8B and 9 could be mounted so as to be tilted by angle θ to the south, southwest, or west.

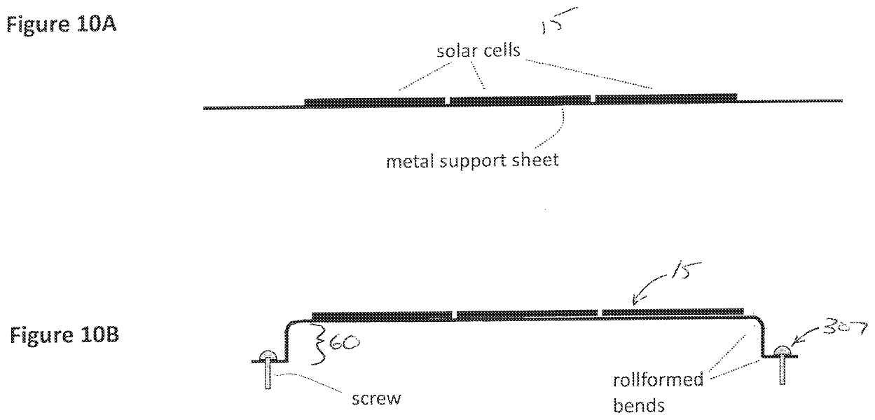

FIGS. 10A and 10B depict a solar cell roofing system that includes solar cell modules having a metal support sheet 50 that has been roll formed to provide for edges that connect directly to a roof surface so that an air passage 400 is positioned between the roof surface and the metal support sheet 50. In one embodiment, the solar cell roofing system includes at least one solar cell 15 that is laminated to a metal support sheet 50. The edges of the metal support sheet 50 are roll formed to provide that the edges of the metal support sheet function as stanchions for direct contact mounting the edges of the metal support sheet to a roof surface so that an air passage is positioned between the roof surface and the metal support sheet.

FIG. 10A depicts a solar cell module 100 including a metal support sheet 50 prior to roll forming, in which the solar cells 15 are positioned to allow for roll forming of the metal support sheet 50 into a geometry for mounting of the solar cell module 100 through fasteners to a metal roof structure, e.g., metal roof structure, in scenarios in which penetration of the roof with the fasteners is possible. FIG. 10B depicts the solar cell module depicted in FIG. 10A following roll forming, in which the roll forming of the metal support sheet 50 provides edges 60 shaped to accommodate attachment of the solar cell module 100 directly to the underlying roof without mounting brackets (such as the mounting brackets 300 depicted in FIGS. 5A-7 and 9). The roll forming that provides the geometry depicted in FIG. 10B may be performed after the lamination of the solar panel modules 100 with a metal support sheet 50. The solar cell module 100 with metal support sheet 50 shown in FIG. 10A could have edges 60 shaped via roll forming to accommodate a different kind of attachment to an underlying roof, for example with screws 307 (as indicated in FIG. 10B) for applications where roof penetration is acceptable. This could save cost compared to the use of a bracket system (as depicted in FIGS. 5A-7) or could be suitable for other kinds of roofs which do not have standing seams or other features to attach brackets to. Other methods and tools to introduce the bends illustrated in FIG. 10 may be envisioned. Other types of rooftop attachment approaches may be envisioned, for which other roof sheet edge profiles may be more suitable; such profiles may also be formed via roll forming (or another method) after lamination of the solar panel with metal support sheet.

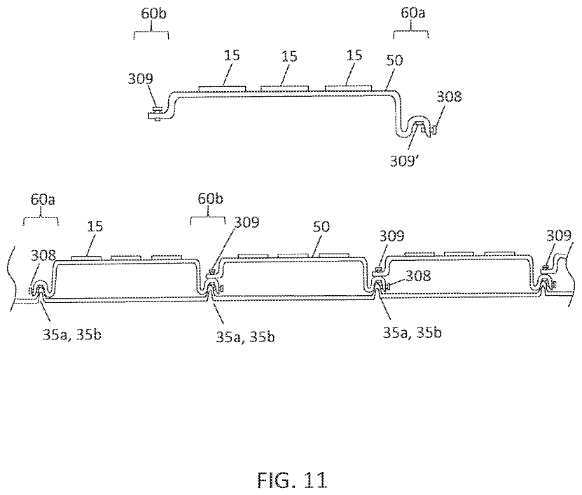

FIG. 11 depicts another embodiment of the present disclosure, in which following lamination of the solar cells 15 to the metal support sheet 50, the metal support sheet 50 can be processed with roll forming to provide edges 60a that engage standing steams 35a, 35b of standing seam metal roofs, or to provide edges 60b that engage the edges of adjacent solar cell modules. This embodiment provides brackets that are integrated into the metal support sheet 50 in a unitary structure.

FIG. 11 depicts a solar cell roofing system comprising a solar cell module 100 including at least one solar cell 15 that is laminated to a metal support sheet 50, the edges of the metal support sheet 50 are roll formed to provide a bracket profile for fastening to a standing seam of a standing seam roof. The bracket profile includes a first type attachment point for engaging a standing seam 35a, 35b of a standing seam metal roof and a second type attachment for engaging the metal support sheet of an adjacent solar cell module.

In some embodiments, at least one of the edges 60a of the metal support sheet 50 is formed to provide a seam engaging attachment point for the metal support sheet 50. The edge 60a of the metal support sheet 50 may have a fastener 308 extending therethrough to contact a standing seam 35a, 35b for abutting roof panels 200 of a metal standing seam roofing system in friction contact. The fastener 308 for engaging the standing seam 35a, 35b may be referred to as a seam engaging fastener 308, and is similar to the fastener illustrated by the structure having reference number 304 in FIG. 5B. In some embodiments, an opposing edge 60b of the metal support sheet 50 may be configured, e.g., by roll forming, to provide an attachment point to an adjacent edge of an installed solar cell module 100 that is attached to a standing seam 35a, 35b. This edge 60b may be referred to as a solar cell module attachment point. A fastener 309 may extend into contact between the two metal support sheets 50 of the abutting solar cell modules 100, in which the fastener 309 engages the abutting solar cell modules to one another. The fastener having reference number 309 is similar to the fastener having reference number 304 depicted in FIG. 5B. For example, the fastener 309 and the sidewall 301b may be in threaded engagement to the edge 30a having a receiving boss 309′ having a thread to engage the thread of the fastener. In this manner, the roof seam engaging fastener 304 may be a screw, and the opening in the receiving boss 309′ may be tapped to have a reciprocal thread.

In all the embodiments described so far, the photovoltaic module components, i.e., solar cells 15 and related components within the solar cell module 100, are laminated with a metal support sheet 50. The metal support sheet 50 is mounted to the roofing structure, but the metal support sheet 50 is not the actual metal roof panel 200 of which a metal roof system is comprised.

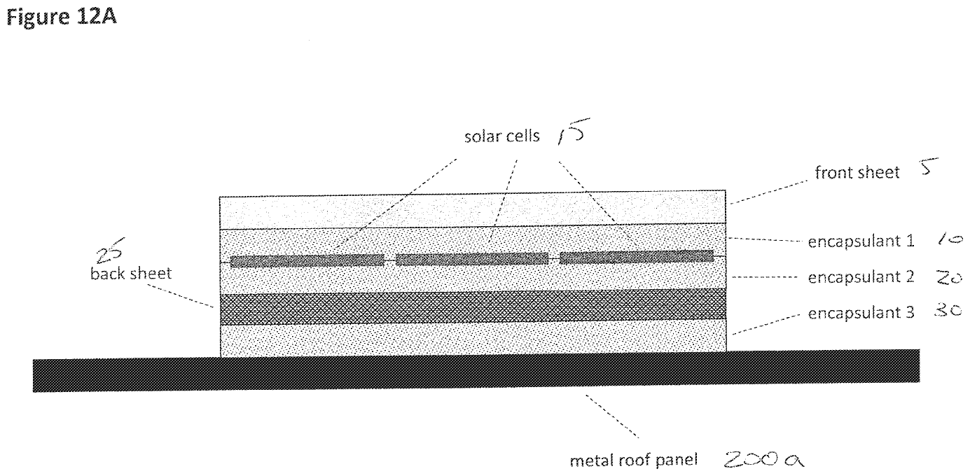

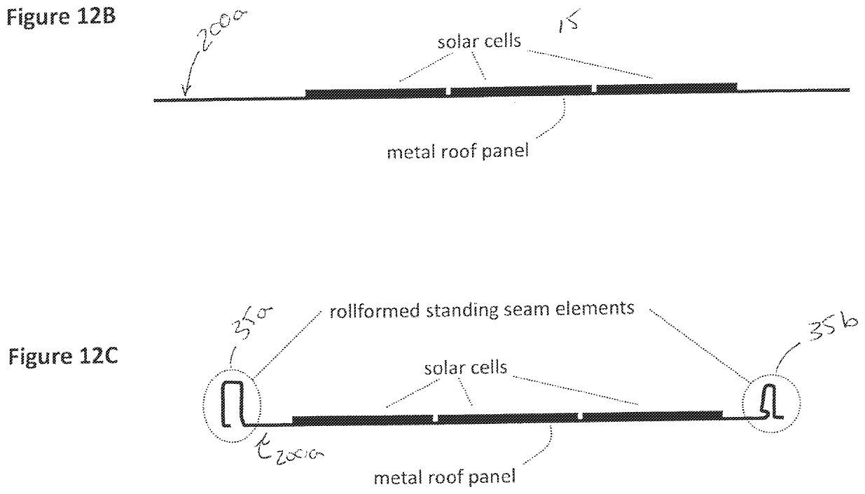

In an alternative approach, as shown in FIG. 12A, these components can be laminated with an actual metal roof panel 200a, for example of gauge 20-26. In some embodiments, the thickness of the metal sheet for the roof panel 200a may range from gauge 22-24. FIG. 12B shows this same PV module laminated with a metal roof panel 200a in simplified view, omitting the front sheet, back sheet, encapsulant sheets, solar cell interconnects, bypass diodes, module connections, junction boxes, etc. These structure have been removed for simplicity, but can be incorporated, and have been described with reference to FIGS. 1A-1C. After lamination, roll forming can then be used to create the standing seam elements 35a, 35b at the edges of the metal roof panel 200a, as show in in FIG. 12C.

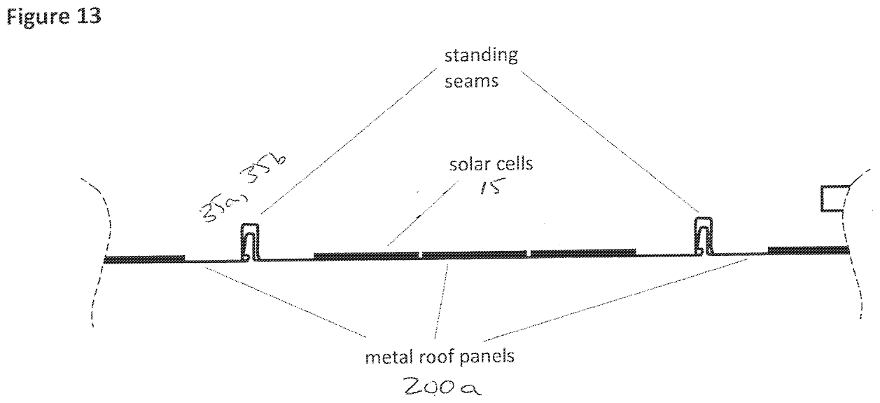

FIG. 13 shows a cross-section of an assembled metal rooftop of the metal roof panels 200a depicted in FIGS. 12A-12C. This approach of laminating the solar module components directly with a metal roof panel 200a may be suitable for new construction, or for re-roofing of existing buildings. This approach eliminates the need for the metal support sheet 50, and also eliminates the need for an attachment system (e.g., brackets) for mounting the solar panel with metal support sheet to the underlying metal roof panels.

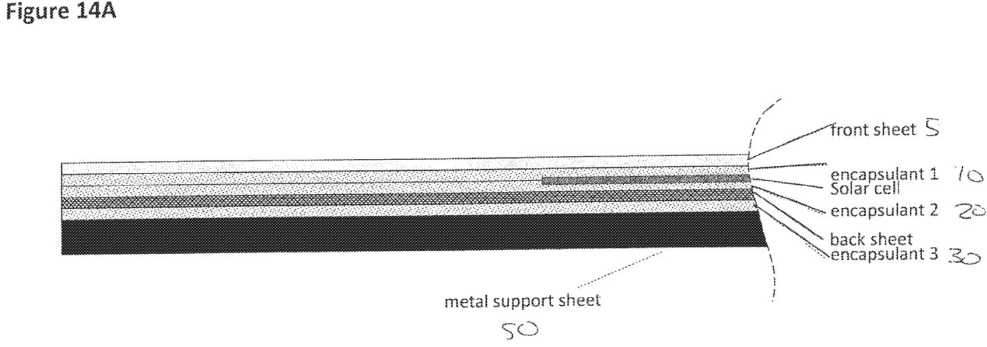

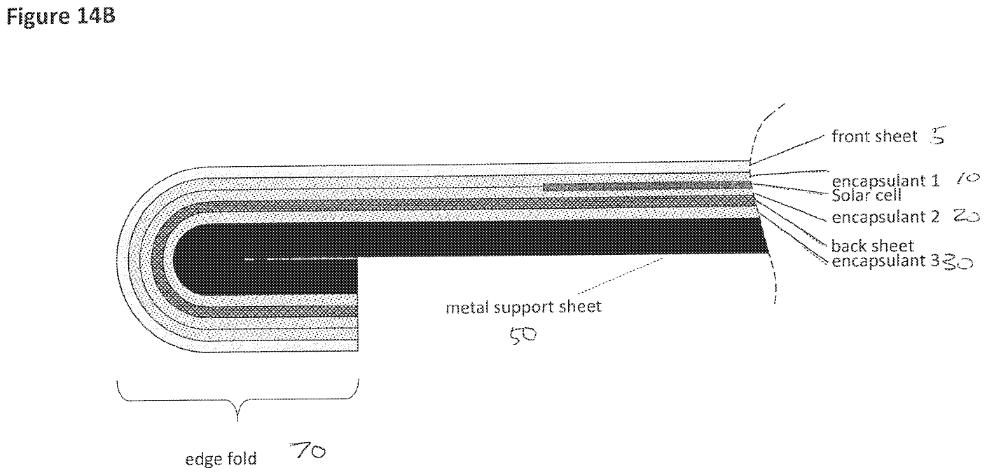

FIGS. 14A and 14B depict another embodiment of the present disclosure. An edge fold 70 can be introduced via roll forming or other bending method, as illustrated in FIG. 14B. FIG. 14A illustrates the structure prior to forming the edge fold 70. The edge fold 70 can provide two advantages. First, the edge fold 70 can create a metal support sheet region that is effectively twice as thick at the edges when compared to the portions of the structure at which the edge fold 70 is not present. When attached to a standing seam roof via a bracket system 300 such as that shown in FIGS. 5A-5C, the regions of the metal support sheet near the brackets will experience high stress under snow loads and high winds. By doubling the effective thickness of the metal support sheet 50 at the edges, the metal support sheet 50 will be able to bear higher stress without mechanical failure. Second, as shown in FIG. 14B the edges of the front sheet, encapsulant layers, and backsheet 50 are folded around to the rear (bottom) of the metal support sheet. This will protect these edges from the more extreme weathering (wind, rain, snow) experienced by the front of the module. This can serve to protect the edge of the module layers from moisture penetration which could lead to delamination or other forms of degradation.

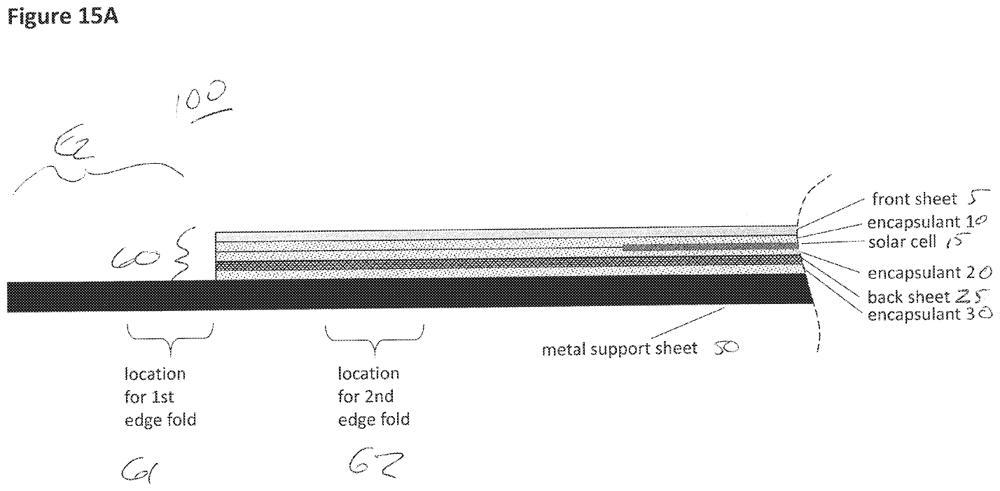

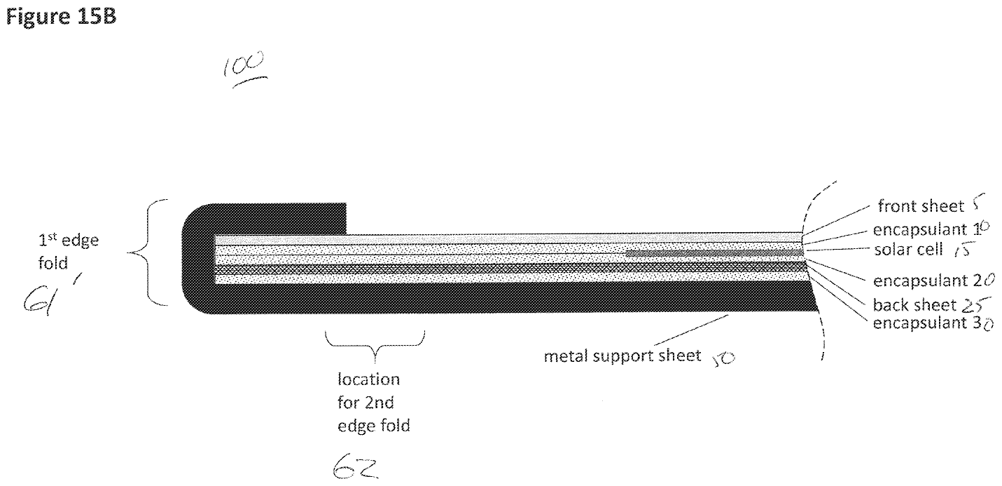

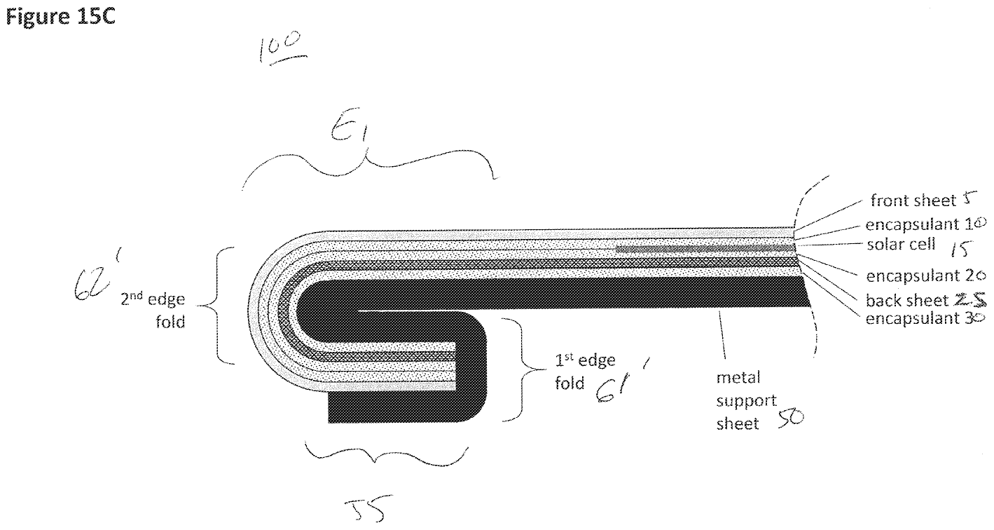

FIGS. 15A, 15B and 15C depict another embodiment of the present disclosure. A first edge fold can be introduced via roll forming or other bending method, as illustrated in FIG. 15B. FIG. 15A illustrates the structure prior to forming the first edge fold. This first edge fold seals the edges of the front sheet, encapsulant layers, and backsheet, suppressing moisture penetration at the edges which could lead to delamination or other forms of degradation. A second edge fold can be introduced via roll forming or other bending method, as illustrated in FIG. 15C, so that the edges of the front sheet, encapsulant layers, and backsheet are folded around to the rear (bottom) of the metal support sheet. This will further protect these edges from the more extreme weathering (wind, rain, snow) experienced by the front of the module.

Referring to FIGS. 15A-15C, in some embodiments, the solar cell module 100 includes at least one solar cell 15; and a metal support sheet 50 that is laminated to the at least one solar cell 15. In this embodiment, at least one least one edge portion E1 of the metal support sheet 50 has a sigmoidal geometry 55 from a perspective of a side view. The term “sigmoidal” or “sigmoid” means S-shaped. The at least one solar cell 15 is present on a planar portion of the metal support sheet 50. The least one solar cell 15 does not extend into the at least one edge portion E1 of the metal support sheet 50.

In some embodiments, engagement of the at least one solar cell 15 to the metal support sheet 50 through lamination, i.e., being laminated, includes a material stack composed of a back sheet encapsulant 30 on the metal support sheet 50, and a back sheet layer 25 on the back sheet encapsulant 30. The material stack further includes a back end encapsulant 20 on the back sheet layer 25, in which the least one solar cell 15 is present on the back end encapsulant 20. In some embodiments, the material stack through which the at least one solar cell 15 is engaged to the metal support sheet 50 further includes a front end encapsulant 10 present on the at least one solar cell 15. In some instances, a polymer front sheet 5 is present atop the front end encapsulant 10.

In some embodiments, the polymer front sheet 5 is composed of a fluoropolymer composition. In one example, the polymer front sheet 5 is composed of ethylene tetrafluoroethylene (ETFE). The polymer front sheet 5 can have a thickness ranging from 25 microns to 200 microns. It is noted that the polymer front sheet 5 depicted in FIGS. 15A-15C is similar to the structure having the same reference number, i.e., reference number 5, in FIGS. 1A-14B. Therefore, further description for the elements having reference number 5 in FIGS. 15A-15C can be found in the above description of the elements having the same reference number 5 in FIGS. 1A-14B.

Referring to FIGS. 15A-15C, each of the back sheet encapsulant 30, the back end encapsulant 20 and the front end encapsulant 10 can be composed of a polymeric composition. For example, the polymeric composition for at least one of the back sheet encapsulant 30, the back end encapsulant 20 and the front end encapsulant 10 can be a composition selected from the group consisting of ethylene-vinyl acetate (EVA), thermoplastic polyurethane, polyolefin and combinations thereof. In some examples, each of these encapsulant layers may have a thickness ranging from 100 microns to 500 microns.

It is noted that the encapsulant layers having reference numbers 10, 20 and 30 that are depicted in FIGS. 15A-15C are similar to the structures having the same reference number, i.e., reference numbers 10, 20 and 30, in FIGS. 1A-14B. Therefore, further description for the elements having reference number 10, 20 and 30 in FIGS. 15A-15C can be found in the above description of the elements having the same reference numbers 10, 20 and 30 in FIGS. 1A-14B.

The solar cell module 100 depicted in FIGS. 15A-15C further includes a solar cell 15 of a type IV semiconductor having an n-type doped region and a p-type doped regions. For example, the solar cells 15 may be silicon (Si) type solar cells. For example, generally a solar cell is made of two types of semiconductors, called p-type and n-type silicon (Si). The p-type silicon is produced by adding atom, such as boron (B) or gallium (Ga), that have one less electron in their outer energy level than does silicon (Si). Because boron has one less electron than is required to form the bonds with the surrounding silicon atoms, an electron vacancy or “hole” is created. The n-type silicon (Si) is made by including atoms that have one more electron in their outer level than does silicon (Si), such as phosphorus (P). Phosphorus (P) has five electrons in its outer energy level, not four. It bonds with its silicon neighbor atoms, but one electron is not involved in bonding. Instead, the electron is free to move inside the silicon structure. A solar cell consists of a layer of p-type silicon (Si) placed next to a layer of n-type silicon (Si). This is only one example of a silicon (Si) solar cell and is provided for illustrative purposes only. Other type IV semiconductors are equally suitable for the base material of the solar cells 15, such as silicon germanium (SiGe) or germanium (Ge), etc. It is not intended that the teachings of this description of the solar cells 15 be limiting. For example, the solar cells 15 are not necessarily composed of type IV semiconductors. In other embodiments, the solar cells 15 can be composed of type III-V semiconductors. A “III-V semiconductor material” is an alloy composed of elements from group III and group V of the periodic table of elements. In one embodiment, the solar cells 15 are comprised of at least one III-V semiconductor material selected from the group consisting of aluminum antimonide (AlSb), aluminum arsenide (AlAs), aluminum nitride (AlN), aluminum phosphide (AlP), gallium arsenide (GaAs), gallium phosphide (GaP), indium antimonide (InSb), indium arsenic (InAs), indium nitride (InN), indium phosphide (InP), aluminum gallium arsenide (AlGaAs), indium gallium phosphide (InGaP), aluminum indium arsenic (AlInAs), aluminum indium antimonide (AlInSb), gallium arsenide nitride (GaAsN), gallium arsenide antimonide (GaAsSb), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), indium arsenide antimonide phosphide (InArSbP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide aluminum antimonide (GaInNAsSb), gallium indium arsenide antimonide phosphide (GaInAsSbP), and combinations thereof.

Still referring to FIGS. 15A-15C, the solar cell module 100 includes a back sheet layer 25 provides for electrical isolation between the metal support sheet and the at least one solar cell. In some embodiments, the back sheet layer 25 is comprised of a polymeric material, such as polyethylene terephthalate (PET). It is noted that back sheet layer 25 having reference number 25 that is depicted in FIGS. 15A-15C is similar to the structure having the same reference number, i.e., reference number 15, in FIGS. 1A-14B. Therefore, further description for the elements having reference number 15 in FIGS. 15A-15C can be found in the above description of the elements having the same reference number 15 in FIGS. 1A-14B.

In some embodiments, the metal support sheet 50 has a composition selected from the group consisting of steel, galvanized steel, aluminum, galvalume and combinations thereof, and the thickness of the metal supporting sheet 50 can range from 24 gauge to 30 gauge. The metal support sheet 50 depicted in FIGS. 15A-15C is similar to the metal support sheet 50 depicted in FIGS. 1A-14B. Therefore, further details on the compositions and thicknesses for the metal support sheet 50 can be found in the above descriptions of the metal support sheet 50 included in the embodiments that are described with reference to FIGS. 1A-14B. Additionally, the metal support sheet 50 may provide the attachment points to roofing that is described above with reference to FIGS. 1A-14B.

FIG. 15A illustrates a solar cell 15 laminated to a portion of a metal support sheet 50, in which the solar cell 15 is laminated to the metal support sheet 50 with a material stack 60 including at least one encapsulant layer 10, 20, 30. Referring to FIG. 15A, at least one edge portion E2 of the metal support sheet 50 is exposed, i.e., is not covered with the material stack 60. The structure depicted in FIG. 15A can provide one example of an initial structure for a method of forming a solar cell module 100. The initial structure can be processed with two deformation process steps using roll forming along a location for a first edge fold 61, and a second edge fold 62.

Metal roll forming tools can be used in forming the metal support sheet 50 along the first and second edge fold locations 61, 62. Roll forming is a continuous bending operation in which a long strip of metal (typically coiled steel) is passed through consecutive sets of rolls, or stands, each performing only an incremental part of the bend until the desired cross-section profile is obtained. Roll forming is ideal for producing parts with long lengths or in large quantities. Such tools are made by, for example, the Bradbury Co., Inc. (Moundridge, Kans.) and would be suitable for the formation of bends in the solar cell module 100, as long as the solar the bends created do not intersect the solar cells 15. Other methods and tools to introduce the bends illustrated in FIGS. 15A-15C may be envisioned.

As described herein, the deformation processing applied to the first and second edge fold locations 61, 62 can deform the at least one edge portion that is exposed onto a portion of the material layer 60 including the encapsulant layers 10, 20, 20 to enclose the at least one edge in a fold having a sigmoidal geometry 55. The fold having the sigmoidal geometry 55 seals the at least one edge portion of the metal support sheet 50.

FIG. 15B illustrates deformation processing, e.g., by roll forming, along the first edge fold location 61′. In the embodiment depicted in FIG. 15B, a base of the material stack 60 including the at least one encapsulant layer 10, 20, 30 is present on an upper surface of the metal support sheet 50, and deforming the at least one edge portion includes a first fold operation to deform the metal support sheet 50 to encapsulate the at least one edge in a first curve (at the first edge fold location 61′) of the metal support sheet 50. The first curve provides the lower curve of the sigmoidal geometry for the encapsulating edge in the finally formed product, as depicted in FIG. 15C.

FIG. 15C illustrates deformation processing, e.g., by roll forming, along the second edge fold location 62′. In some embodiments, deforming the at least edge portion includes a second folding operation to deform the metal support sheet 50 in an opposite direction as the first forming operation that provided the first curve (at the first edge fold location 61′). The second folding operation provides a second curve (at the second fold location 62′) that provides an upper curve of the sigmoidal geometry.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

While the methods and structures of the present disclosure have been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. A solar cell roofing system comprising:
a solar cell module including at least one solar cell that is laminated to a metal support sheet; and
at least one bracket having a first type attachment point for engaging a standing seam of a standing seam metal roof and a second type attachment for engaging the metal support sheet of an adjacent solar cell module, wherein during engagement of the solar cell module to the bracket, and engagement of the bracket to the standing seam, at least the metal support sheet is engaged in tension.

2. The solar cell roofing system of claim 1, wherein the solar cell module is planar.

3. The solar cell roofing system of claim 1, wherein sidewalls along a length of the second type attachment point are perpendicular to sidewalls along a height of the first type attachment point.

4. The solar cell roofing system of claim 1, wherein the first type attachment point includes a fastener for friction engagement to the standing seam.

5. The solar cell roofing system of claim 3, wherein the second type attachment point includes a fastener for extending through an opening of the sidewalls of the second type attachment point, wherein the fastener extends through an opening through a portion of the metal support sheet that is positioned within the second type attachment point.

6. The solar cell roofing system of claim 1, wherein the metal supporting sheet has a thickness ranging from 24 gauge to 30 gauge.

7. The solar cell roofing system of claim 1, wherein during engagement to the standing seam of the stranding seam metal roof, the lower surface of the metal support sheet that is underlying the solar cell module is parallel to an upper surface of the standing seam metal roof that is between the standing seams.

8. The solar cell roofing system of claim 1, wherein the tension maintains the engagement to the standing seam metal roof under loading conditions from wind and snow.

9. A solar cell roofing system comprising:
a solar cell module including at least one solar cell that is laminated to a metal support sheet, wherein the edges of the metal support sheet are formed to provide that the solar cell modules are titled towards a light source in a position engaged to a standing seam metal roof; and
at least one bracket having a first type attachment point for engaging a standing seam of a standing seam metal roof and a second type attachment for engaging the metal support sheet of the solar cell module.

10. The solar cell roofing system of claim 9, wherein an angle of tilt to provide that at least one solar cell is titled towards the light source ranges from 5 degrees to 25 degrees, the angle of tilt defined at an intersection of the back surface of the metal supporting sheet that is underlying the solar cells and an upper surface of the standing seam metal roof.

11. The solar cell roofing system of claim 9, wherein the metal supporting sheet has a thickness ranging from 24 gauge to 28 gauge.

12. A method of forming a solar module comprising:
laminating a solar cell to a laminate portion of a metal support sheet, the solar cell being laminated to the metal support sheet with a material stack including at least one encapsulant layer; and
deforming at least one edge portion of the metal support sheet to produce standing seam profiles, a first profile of the standing seam profiles providing a male leg being positioned on a first side of the metal support sheet and a second profile of the standing seam profiles providing a female leg being positioned at an opposing second side of the metal support sheet.

13. The method of claim 12, wherein the edge portions are not covered by the at least one encapsulant when the solar cell is laminated to the laminate portion of the metal support sheet, and the deforming of the at least one edge portion includes deforming the edge portions onto the encapsulant layer that is overlying the laminate portion of the metal support sheet to enclose at least one of the first and second side of the metal sheet in a fold.

14. The method of claim 13, wherein the fold has a sigmoidal geometry from a perspective of a side view.

15. The method of claim 14, wherein the fold having the sigmoidal geometry seals at least one edge portion of the metal support sheet.

16. The method of claim 14, wherein a base of the material stack including at least one encapsulant layer is present on an upper surface of the metal support sheet, wherein said deforming the at least one edge portion includes a first fold operation to deform the metal support sheet to encapsulate the at least one edge in a first curve of the metal support sheet, the first curve providing the lower curve of the sigmoidal geometry.

17. The method of claim 16, wherein said deforming the at least edge portion includes a second folding operation to deform the metal support sheet in an opposite direction as the first forming operation that provided the first curve, wherein the second folding operation provides a second curve that provides an upper curve of the sigmoidal geometry.

18. The method of claim 12, wherein a laminate portion of the metal support sheet is planar.

19. The method of claim 12, wherein the metal supporting sheet has a thickness ranging from 24 gauge to 28 gauge.

20. The method of claim 12, wherein the at least one least one encapsulant layer has a composition that is selected from the group consisting of ethylene-vinyl acetate (EVA), thermoplastic polyurethane (TPU), polyolefin and combinations thereof.
